(19) United States
(12) Patent Application Publication
(10) Pub. No.: US 2006/0148275 A1
(43) Pub. Date: Jul. 6, 2006

(54) Method of forming an alignment mark and manufacturing a semiconductor device using the same

(76) Inventors: Young-Koog Han, Seoul (KR); Dae-Joung Kim, Gyeonggi-do (KR); Eun-Sung Kim, Seoul (KR); Jae-Hoon Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/325,208

(22) Filed: Jan. 3, 2006

(30) Foreign Application Priority Data
Jan. 3, 2005 (KR) 2005-0000009

(51) Int. Cl. H01L 21/00

(52) U.S. Cl. 438/800

(57) ABSTRACT

Embodiments of the present invention provide, among other things, a method of forming an alignment mark having a stepped structure without an additional process. The alignment mark may be used to prevent formation of a defect source in a semiconductor device.

### CROSS REFERENCE TO RELATED APPLICATIONS

This application claims priority under 35 U.S.C. § 119 to Korean Patent Application No. 2005-0000009, filed on Jan. 3, 2005, the contents of which are herein incorporated by reference in its entirety for all purposes.

### BACKGROUND

1. Field of the Invention

This disclosure relates to a method of forming an alignment mark. The alignment mark may be used for identifying an alignment between a photo mask and a semiconductor substrate or between overlapped upper and lower patterns.

2. Description of the Related Art

In general, forming a semiconductor device includes transcribing an image of a photo mask onto a semiconductor substrate. Before the image of the photo mask is transcribed, the photo mask is aligned with the semiconductor substrate using an alignment mark. Alignment marks are important because when the photo mask is not accurately aligned with the semiconductor substrate, the image of the photo mask is not precisely transcribed into the semiconductor substrate. Inaccurate photo mask alignment can create a host of problems. Moreover, misalignment can also cause prevent an upper pattern from being accurately overlapped with a lower pattern.

In a conventional method alignment method, a stepped portion between a surface of a local oxidation of silicon (LOCOS) isolation layer and a surface of a semiconductor substrate is used as an alignment mark. The stepped portion defined by the LOCOS isolation layer remains over the course of several processes, thus there is no problem in using the stepped portion as the alignment mark.

However, LOCOS isolation layers are not employed in recent semiconductor devices. Recently, a trench isolation layer has been used in place of the LOCOS isolation layer in the manufacturing of semiconductor devices. It is very difficult to form an alignment mark when the trench isolation layer is used because a stepped portion is not formed between a surface of the trench isolation layer and a surface of a semiconductor substrate.

As a result, additional processes are carried out to form the alignment mark when the trench isolation layer is used. Methods of forming an alignment mark are disclosed in Korean Patent Laid Open Publication No. 2001-046915 and Japanese Patent Laid Open Publication No. 2002-134701. However, since additional processes for forming an alignment mark are performed in the above-mentioned methods, a process for manufacturing a semiconductor device is complicated.

In particular, in one conventional method, a trench where an alignment mark is to be formed is filled with a structure including oxide and polysilicon. The structure has a flat upper face positioned on a plane substantially identical to that on which an upper face of the semiconductor substrate is placed. Since the surfaces are in the same plane, the structure in the trench is partially etched to form a stepped portion as the alignment mark.

Disadvantageously, when the structure is partially etched to form the stepped portion as shown in FIG. 1, a protruded portion 1 is frequently formed. After the protruded portion 1 is removed in a subsequent process, particles generated from the protruded portion 1 remain on the semiconductor substrate. The particles act as a source of defects in the semiconductor device.

As described above, the process of forming the stepped alignment mark in the semiconductor device having the trench isolation layer is complicated due to the additional steps. As a result, productivity of the semiconductor device manufacturing process is decreased. Also, the additional steps generate particles acting as a defect source causing the semiconductor device to have inferior reliability. Embodiments of the present invention solve these and other prior art problems.

### SUMMARY

Embodiments of the present invention provide, among other things, a method of forming an alignment mark having a stepped structure without an additional process. The alignment mark may be used to prevent formation of a defect source in a semiconductor device.

In a method of forming an alignment mark in accordance with one aspect of the present invention, a first portion of a polysilicon layer is formed above a substrate and a second portion of the polysilicon layer is formed in a trench in the substrate. Next, the first portion of the polysilicon layer is patterned. At substantially the same time, the second portion of the polysilicon layer is removed to form an alignment mark without an additional process. The alignment mark has a stepped structure corresponding to an upper end portion of the trench.

### BRIEF DESCRIPTION OF THE DRAWINGS

FIG. 1 is a picture illustrating an alignment mark of a semiconductor device in accordance with a conventional method.

FIGS. 2A to 2D are cross sectional views illustrating a method of manufacturing a semiconductor device in accordance with a first embodiment of the present invention.

FIG. 3 is a plan view illustrating a chip region and a predetermined region in FIG. 2A.

FIGS. 4A to 4G are cross sectional views illustrating a method of manufacturing a semiconductor device in accordance with a second embodiment of the present invention.

FIGS. 5A to 5E are cross sectional views illustrating a method of manufacturing a semiconductor device in accordance with a third embodiment of the present invention.

### DETAILED DESCRIPTION

Embodiments of the present invention are described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

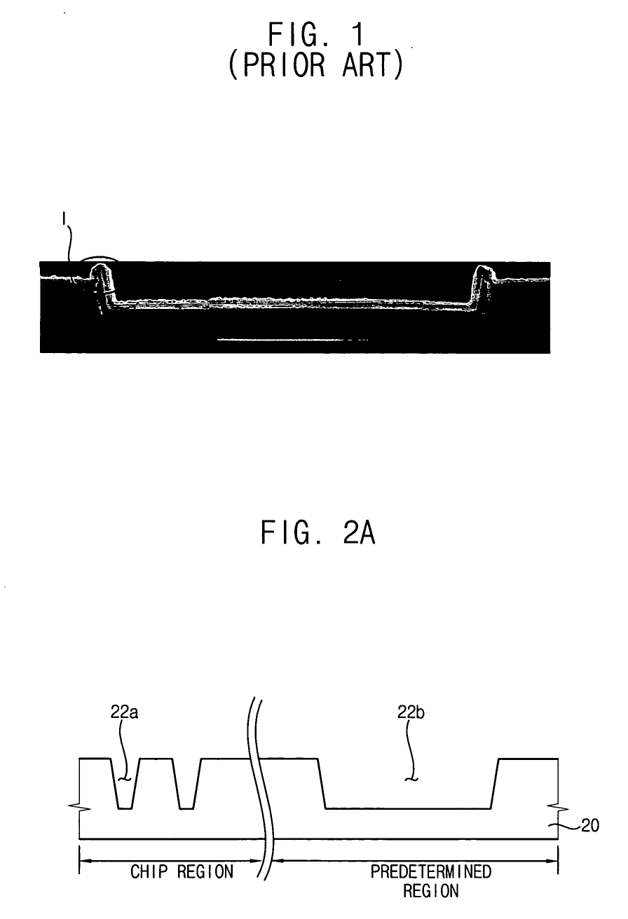

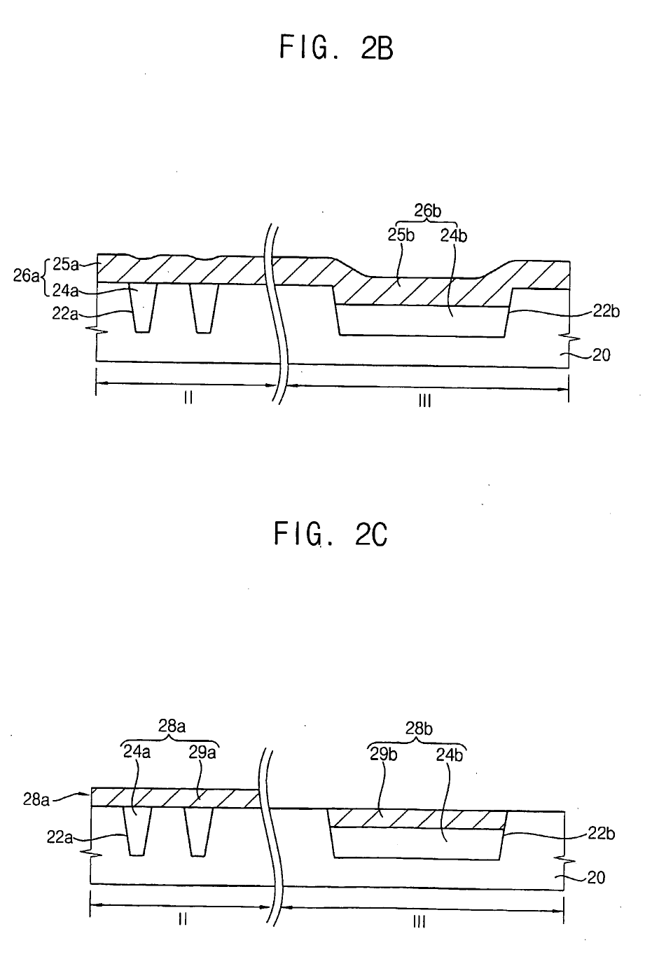

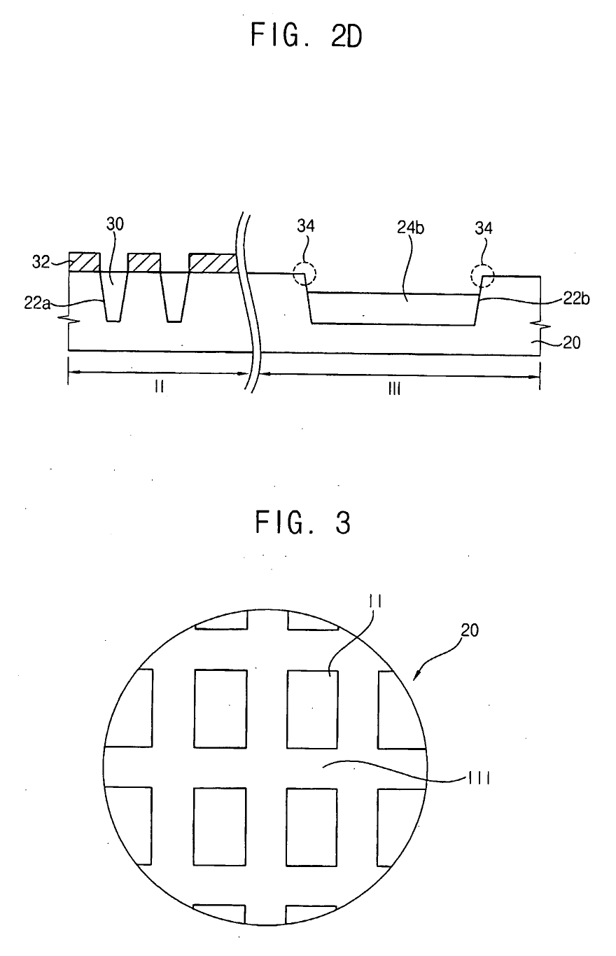

FIGS. 2A to 2D are cross sectional views illustrating a method of manufacturing a semiconductor device in accordance with a first embodiment of the present invention.

Referring to FIG. 2A, a semiconductor substrate 20 having a chip region II where a semiconductor structure is formed and a predetermined region III where an alignment mark is to be formed is prepared.

Particularly, referring to FIG. 3, the chip region II corresponds to a region where a semiconductor structure, such as a gate structure, a metal wiring, etc., is formed. The predetermined region III corresponds to a scribe lane that is cut for dividing the semiconductor substrate 20 into unit chips. The chip region II may include a cell region where an integrated circuit device such as a gate structure may be formed, and a peripheral region where the metal wiring may be formed.

Referring back to FIG. 2A, a first trench 22a and a second trench 22b are formed at surface portions of the semiconductor substrate 20 in the chip region II and the predetermined region III, respectively. The first and second trenches 22a and 22b may be formed simultaneously with each other. Here, the second trench 22b in the predetermined region III has an aspect ratio lower than that of the first trench 22a in the chip region II.

Referring to FIG. 2B, a first preliminary structure 26a including both a first oxide layer 24a and a first preliminary polysilicon layer 25a may be formed on the semiconductor substrate 20 in the chip region. Simultaneously, a second preliminary structure 26b including both a second oxide layer 24b and a second preliminary polysilicon layer 25b may be formed on the semiconductor substrate 20 in the predetermined region III. Thus, the first and second oxide layers 24a and 24b may be a substantially same material and the first and second preliminary polysilicon layers 25a and 25b may be a substantially same material. In this embodiment, the first oxide layer 24a in the first trench 22a forms an isolation layer.

The first trench 22a may be fully filled with the first oxide layer 24a and in contrast the second trench 22b may be partially filled with the second oxide layer 24b. Also, the first preliminary polysilicon layer 25a is partially positioned above the trench 22a and on the first oxide layer 24a while in contrast the second preliminary polysilicon layer 25b is partially placed in the trench 22b and on the second oxide layer 24b. The different profiles of the trenches 22a and 22b may cause the first preliminary structure 26a to have a profile different from that of the second preliminary structure 26b.

Although it is shown that the first and second preliminary structures 26a and 26b include the first and second oxide layers 24a and 24b, respectively, and the first and second preliminary polysilicon layers 25a and 25b, respectively, alternative layers may be used. Furthermore, the first and second preliminary structures 26a and 26b may further include other layers in addition to the oxide layers 24a and 24b and the preliminary polysilicon layers 25a and 25b.

Referring to FIG. 2C, an upper surface of the first preliminary structure 26a may be partially removed by a chemical mechanical polishing (CMP) process or any other method. Thus, a first structure 28a including both the first oxide layer 24a and a first polysilicon layer 29a may be formed in the chip region. Also, an upper surface of the second preliminary structure 26b may be planarized by a CMP process or any other method to expose the semiconductor substrate 20. Thus, a second structure 28b including both the second oxide layer 24b and a second polysilicon layer 29b may be formed in the predetermined region. The second structure 28b may completely fill up the second trench 22b.

Referring to FIG. 2D, the first polysilicon layer 29a in the chip region may be patterned to form an isolation layer 30 in the first trench 22a. Simultaneously, the second polysilicon layer 29b in the predetermined region may be removed to form an alignment mark 34 having a stepped structure in the second trench 22b. The stepped structure of the alignment mark 34 may correspond to an upper end portion of the second trench 22b.

According to the present embodiment, the alignment mark 34 may be formed without additional processes being performed. More specifically, the alignment mark 34 may be formed substantially simultaneously with the patterning process in the chip region. Thus, the alignment mark 34 may be readily formed without additional processes. Moreover, a defect source may be advantageously avoided.

Next, the second oxide layer 24b in the second trench 22b of the predetermined region may be fully or partially removed. Fully or partially removing the second oxide layer 24b in the second trench 22b of the predetermined region causes the alignment mark 34 to have a high stepped structure. The first oxide layer 24a may be fully or partially removed at the same time as the second oxide layer 22b.

Advantageously the stepped structure of the alignment mark 34 may still remain after performing subsequent processes. As a result, the alignment mark 34 may be continuously used during subsequent processes.

### Embodiment 2

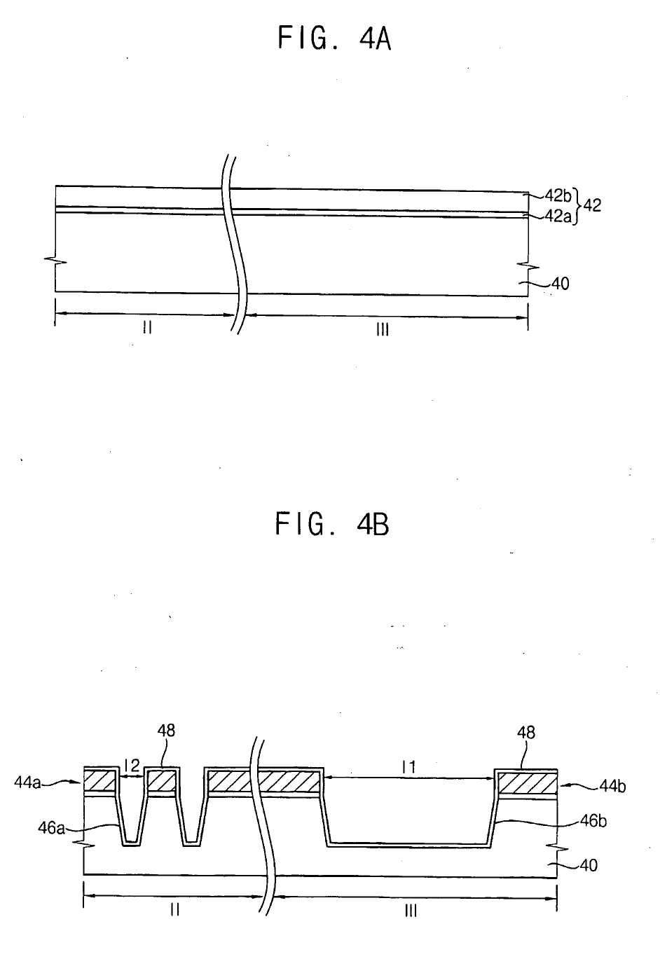

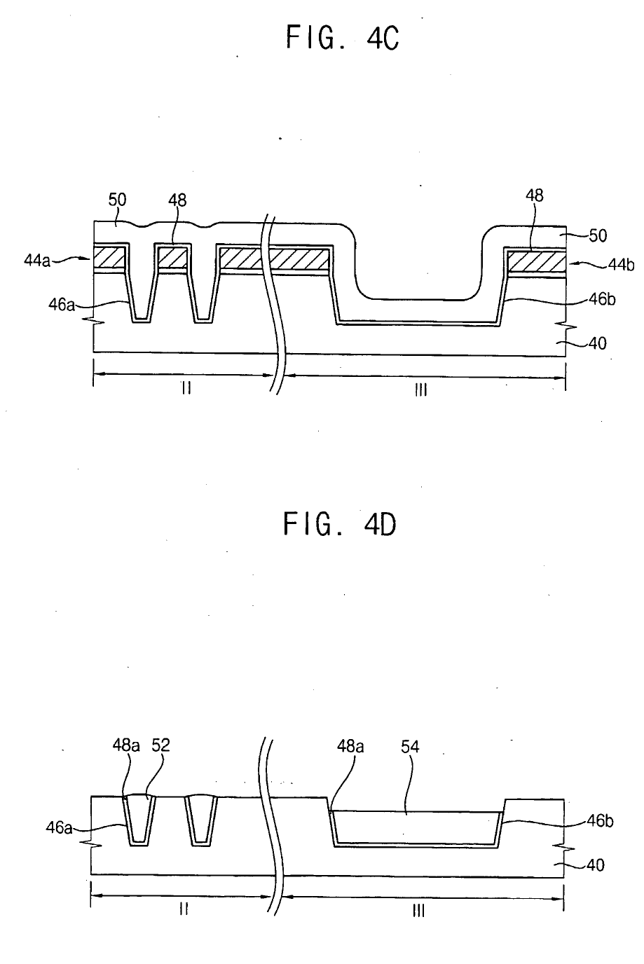

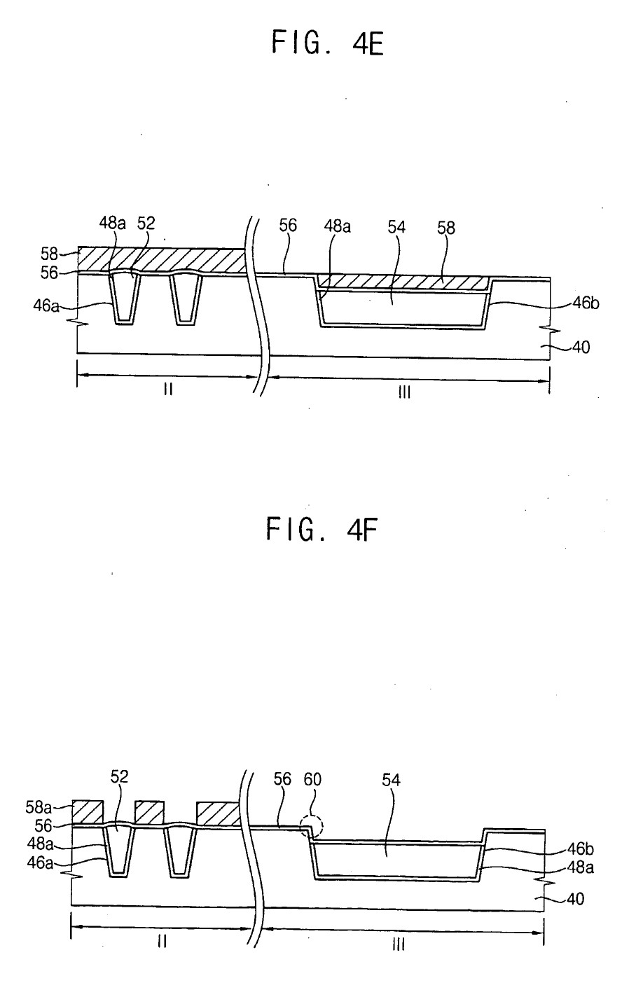

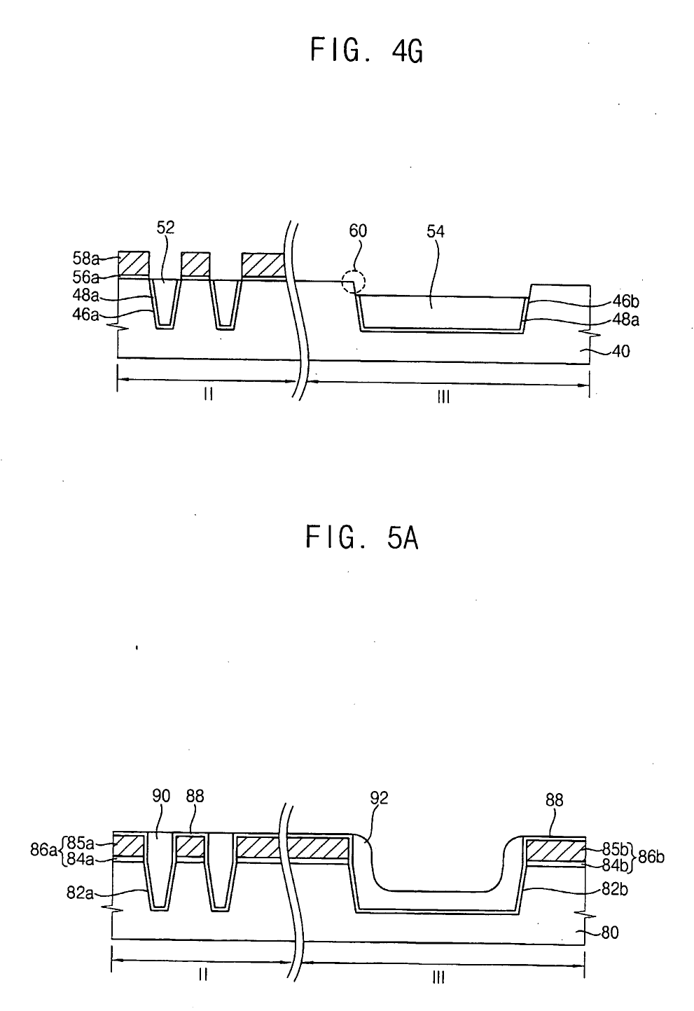

FIGS. 4A to 4G are cross sectional views illustrating a method of manufacturing a semiconductor device in accordance with a second embodiment of the present invention.

Referring to FIG. 4A, a hard mask layer 42 is formed on a semiconductor substrate 40 having a chip region and a predetermined region. The chip region and the predetermined region may be substantially identical to those in Embodiment 1. The hard mask layer 42 may include both a pad oxide layer 42a and a pad nitride layer 42b formed on the pad oxide layer 42a. The pad oxide layer 42a may have a thickness of about 50 to 100 Å and may be formed by a chemical vapor deposition (CVD) process or any other method. The pad nitride layer 42b may have a thickness of about 300 to 500 Å and may also be formed by a CVD process or any other method.

Referring to FIG. 4B, the hard mask layer 42 may be patterned by a photolithography process to form both a first hard mask pattern 44a exposing the semiconductor substrate 40 in the chip region and a second hard mask pattern 44b exposing the semiconductor substrate 40 in the predetermined region. The second hard mask pattern 44b may have a width 11 that is wider than a width 12 of the first hard mask pattern 44a.

The semiconductor substrate 40 may be partially etched using the first and second hard mask patterns 44a and 44b as an etching mask to form a first trench 46a having a first aspect ratio in the chip region and a second trench 46b having a second aspect ratio in the predetermined region. The second aspect ratio may be lower than the first aspect ratio.

Optionally, the semiconductor substrate 40 may be thermally treated to cure damages in the semiconductor substrate 40 generated during formation of the first and second trenches 46a and 46b. To further cure the damages in the semiconductor substrate 40, a buffer oxide layer 48 may be formed on upper surfaces of the first and second hard mask patterns 44a and 44b, and side and bottom walls of the first and second trenches 46a and 46b. The buffer oxide layer 48 may have a thickness of about 5 to 100 Å and may be formed by a CVD process or any other method.

Referring to FIG. 4C, an oxide layer 50 having a good gap-filling characteristic may be formed on the buffer oxide layer 48 by a high-density plasma CVD process or any other method. After the oxide layer 50 is formed, the first trench 46a in the chip region is fully filled with the oxide layer 50. Conversely, the oxide layer 50 in the predetermined region includes a profile substantially similar to that of the second trench 46b and does not fully fill the second trench 46b. As a result, the oxide layer 50 in the chip region has an upper face higher than that of the oxide layer 50 in the predetermined region.

Referring to FIG. 4D, the oxide layer 50 may be planarized through a CMP process or any other method to expose the surfaces of the first and second hard mask patterns 44a and 44b. The exposed first and second hard mask patterns 44a and 44b may be removed by a strip process using a phosphorous solution or any other method.

The oxide layer 50 may be removed by a CMP process, an etch-back process, or any other method until the surface of the semiconductor substrate 40 is exposed to form an isolation layer 52 in the first trench 46a of the chip region. After the removal process, the oxide layer 50 in the predetermined region partially remains in the second trench 46b so that an oxide structure 54 having an upper face lower than that of the semiconductor substrate 40 is formed in the second trench 46b. Further, buffer oxide layers 48a remain both between the isolation layer 52 and the inner face of the first trench 46a and between the oxide structure 54 and the inner face of the second trench 46b.

Referring to FIG. 4E, a tunnel oxide layer 56 and a polysilicon layer 58 may be sequentially formed on the semiconductor substrate 40, the isolation layer 52, the remaining buffer oxide layers 48a and the oxide structure 54. The tunnel oxide layer 56 may have a thickness of about 5 to 100 Å and may be formed by a thermal oxidation process, a CVD process or any other method. The polysilicon oxide layer 58 may have a thickness of about 200 to 500 Å and may be formed by a thermal oxidation process, a CVD process or any other method. The tunnel oxide layer 56 and the polysilicon layer 58 in the predetermined region may have stepped profiles substantially similar to a stepped structure between the semiconductor substrate 40 and the oxide structure 54.

The polysilicon layer 58 may be planarized by a CMP process. Planarization may leave the polysilicon layer 58 above the trench 46a in the chip region. In contrast, planarization in the predetermined region may leave the polysilicon layer 58 fully filling up the second trench 46b. In other words, the polysilicon layer 58 in the predetermined region may have a flat upper face that is positioned on a plane substantially identical to that on which an upper face of the tunnel oxide layer 56 exists.

Referring to FIG. 4F, the polysilicon layer 58 in the chip region may be patterned by a photolithography process or any other method to form a polysilicon layer pattern 58a. Simultaneously, the polysilicon layer 58 in the predetermined region may be completely removed to form an alignment mark 60 having a stepped structure. The stepped structure of the alignment mark 60 corresponds to an upper end portion of the second trench 46b.

Referring to FIG. 4G, portions of the tunnel oxide layer 56 exposed through the polysilicon layer pattern 58a may be removed to form a tunnel oxide layer pattern 56a in the chip region. Simultaneously, portions of the tunnel oxide layer 56 in the predetermined region may be removed to form a high stepped structure of the alignment mark 60.

Optionally, in the chip region, the isolation layer 52 and the remaining buffer oxide layer 48a may be partially removed. Simultaneously, in the predetermined region, the oxide structure 54 and the remaining buffer oxide layer 48a may be partially removed so that the stepped structure of the alignment mark 60 may have a much higher step.

A dielectric layer (not shown) and a polysilicon layer (not shown) may be sequentially formed on the polysilicon layer pattern 58a to complete a gate structure of a flash memory device. With respect to the optional gate structure, the lower polysilicon layer pattern 58a may correspond to a floating gate and the upper polysilicon layer may correspond to a control gate.

According to the present embodiment, the alignment mark 60 may be formed without additional processes being performed. In other words, the alignment mark 60 may be formed simultaneously with the patterning process in the chip region. Thus, the method of forming the alignment mark 60 in accordance with the present embodiment may be advantageously employed in manufacturing the flash memory device.

Thus, the alignment mark 60 may be readily and easily formed. Further, a defect source caused by the additional processes may be avoided. Advantageously the stepped structure of the alignment mark 34 may still remain after performing subsequent processes. As a result, the alignment mark 34 may be continuously used during subsequent processes.

### Embodiment 3

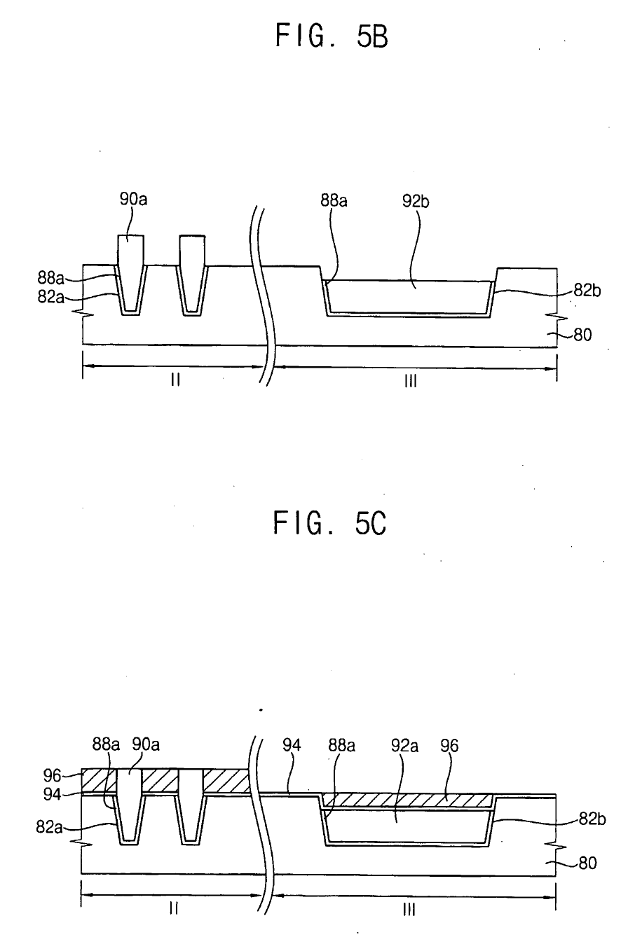

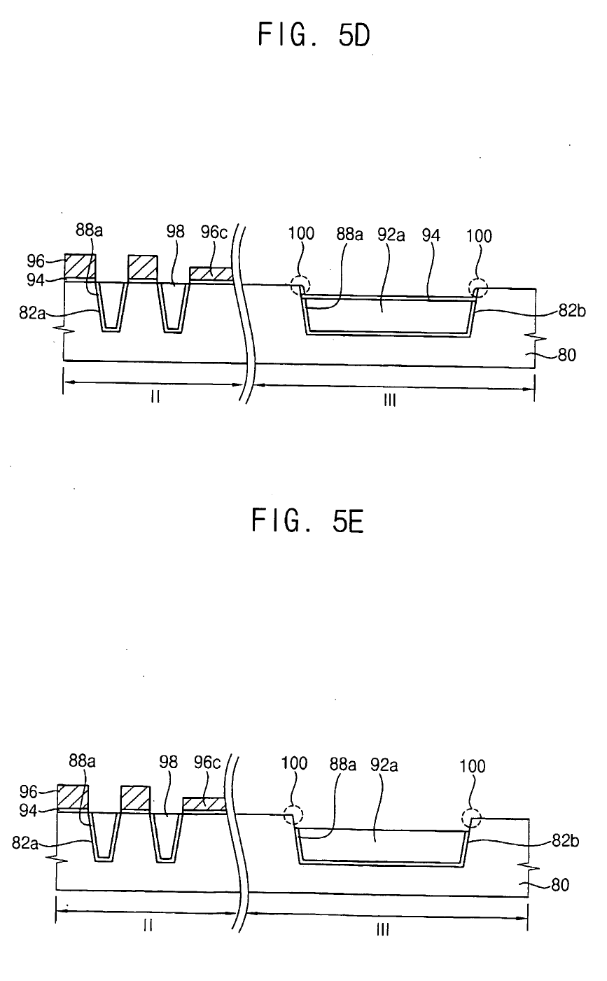

FIGS. 5A to 5E are cross sectional views illustrating a method of manufacturing a semiconductor device in accordance with a third embodiment of the present invention.

Referring to FIG. 5A, processes in the same manner as illustrated with reference to FIGS. 4A to 4C may be carried out to form an oxide layer (not shown) on a semiconductor substrate 80 having first and second trenches 82a and 82b. The semiconductor substrate 80 may have a chip region and a predetermined region substantially the same as in Embodiment 1, respectively. The substrate may also include a buffer oxide layer 88.

After forming the oxide layer (not shown), the oxide layer may be removed by a CMP process, an etch back process or any other method to expose first and second hard mask patterns 86a and 86b, to form a first structure 90 in the chip region, and a second structure 92 in the predetermined region. Each of the first and second hard mask patterns 86a and 86b may include both pad oxide layer patterns 84a and 84b and pad nitride layer patterns 85a and 85b, respectively. The resulting second structure 92 may have a profile substantially similar to that of the second trench 82b. As illustrated in Embodiment 1, since the second trench 82b has an aspect ratio lower than that of the first trench 82a, the second structure 92 has a height lower than that of the first structure 90.

Referring to FIG. 5B, the first and second hard mask patterns 86a and 86b may be removed to form a first structure pattern 90a in the chip region and a second structure pattern 92b in the predetermined region. Since the second structure 92 may have a height lower than that of the substrate 80, the second structure pattern 92b may have a stepped structure at an upper end of the second trench 82b. Buffer oxide layer 88a may remain after removing the first and second hard mask patterns 86a and 86b.

Referring to FIG. 5C, a tunnel oxide layer (not shown) and a polysilicon layer (not shown) may be sequentially formed on the semiconductor substrate 80. The tunnel oxide layer and the polysilicon layer formed in the predetermined region may have profiles substantially similar to that of the second structure pattern 92b.

The polysilicon layer may be removed by a CMP process or any other method to expose the first structure pattern 90a. As a result, nodes of the polysilicon layer are separated from each other to form a polysilicon layer pattern 96 in the chip region. Still referring to the chip region, the tunnel oxide layer may be simultaneously converted into a tunnel oxide layer pattern 94. In other words, spaces between the first structure patterns 90a may be filled with the polysilicon layer pattern 96 in the chip region. Referring now to the predetermined region, as a result of the partial removal of the polysilicon layer the second trench 82b may be filled with the polysilicon layer pattern 96 thereby completely filling up the second trench 82b.

Referring to FIG. 5D, the first structure 90a may be partially removed to form an isolation layer 98 that fully fills up the first trench 82a. Simultaneously, the tunnel oxide layer pattern 94 in the predetermined region may be partially removed.

Next, at least some of the polysilicon layer pattern 96c may be removed so that a polysilicon layer pattern 96c in a peripheral region of the chip region may have a height lower than that of the polysilicon layer pattern 96 in a cell region of the chip region. Simultaneously, the polysilicon layer pattern 96 in the second trench 82b may be removed to form an alignment mark 100 having a stepped structure that corresponds to the upper end portion of the second trench 82b.

Referring to FIG. 5E, both the remaining buffer oxide layer 88a in the chip region and other materials remaining after forming the isolation layer 98 may be removed. Simultaneously, the tunnel oxide layer pattern 94 in the predetermined region may be removed so that the stepped structure of the alignment mark 100 has a higher step.

A dielectric layer (not shown) and a polysilicon layer (not shown) may be sequentially formed on the polysilicon layer pattern 96. The dielectric layer and the polysilicon layer may be patterned to complete a gate structure of a flash memory device. With respect to the gate structure, the lower polysilicon layer pattern 96 may correspond to a floating gate and the upper polysilicon layer may correspond to a control gate.

According to the present embodiment, the alignment mark 100 may be formed without additional processes. More specifically, the alignment mark 100 may be formed simultaneously with the patterning process in the chip region. The method of forming the alignment mark 100 in accordance with the present embodiment may be employed in manufacturing flash memory devices.

Thus, the alignment mark 100 may be readily and easily formed. Further, a defect source may be avoided. Advantageously the stepped structure of the alignment mark 34 may still remain after performing subsequent processes. As a result, the alignment mark 34 may be continuously used during subsequent processes.

Thus, productivity of the semiconductor device manufacturing process may be improved. Further, since the alignment mark having the stepped structure does not cause a defect source, failures of the semiconductor devices may be greatly reduced. As a result, the semiconductor device manufactured using embodiments of the present invention may have improved reliability.

According to the present invention, although the semiconductor device has the trench isolation layer, the alignment mark having the stepped structure may be formed without additional processes being performed. That is, the polysilicon layer in the trench of the predetermined region is removed simultaneously with the polysilicon layer of the structure in the chip regions being removed so that the alignment mark having the stepped structure is formed in the predetermined region. Thus, the alignment mark having the stepped structure may be readily formed by a simple process without a defect source being generated.

Having described the preferred embodiments of the present invention, it is noted that modifications and variations can be made by persons skilled in the art in light of the above teachings. It is therefore to be understood that changes may be made, in the particular embodiments of the present invention disclosed, which are within the scope and the spirit of the invention outlined by the appended claims.

What is claimed is:

1. A method of forming an alignment mark, comprising:
forming a first portion of a polysilicon layer above both an isolation layer trench in a substrate and the substrate and forming a second portion of the polysilicon layer in a wide trench in the substrate, the first and second portions being located in different lateral regions; and
forming the alignment mark by removing at least some of the second portion of the polysilicon layer at substantially the same time the first portion of the polysilicon layer is patterned, the alignment mark having a stepped structure corresponding to an upper end portion of the wide trench.

2. The method of claim 1, wherein the lateral region having the first portion of the polysilicon layer comprises chip regions of a semiconductor device and the lateral region having the second portion of the polysilicon layer comprises a scribe lane between the chip regions.

3. The method of claim 1, further comprising forming the wide trench and the isolation layer trench at substantially the same time.

4. The method of claim 1, further comprising removing at least a portion of an oxide layer located in the wide trench to further expose the wide trench.

5. The method of claim 4, wherein removing at least a portion of the oxide layer located in the wide trench is carried out simultaneously with removing at least a portion of an oxide layer located in the isolation layer trench.

6. The method of claim 4, wherein at least a portion of the oxide layer in the wide trench is removed by a chemical mechanical polishing (CMP) process.

7. The method of claim 1, wherein the different lateral regions do not include a local oxidation of silicon (LOCOS) isolation layer.

8. A method of manufacturing a semiconductor device, comprising:
preparing a substrate having a chip region and a laterally adjacent non-chip region where an alignment mark is to be formed, the chip region having an isolation trench filled up with an insulating material and the non-chip region having a smaller aspect ratio trench partially filled up with the insulating material;
sequentially forming a tunnel oxide layer and a polysilicon layer on the substrate and the insulating material thereby further filling the smaller aspect ratio trench in the non-chip region; and
partially removing the polysilicon layer to substantially simultaneously form both a polysilicon layer pattern in the chip region and an alignment mark having a stepped structure in the non-chip region, the stepped structure corresponding to an upper end portion of the smaller aspect ratio trench.

9. The method of claim 8, wherein the non-chip region comprises a scribe lane.

10. The method of claim 8, further comprising:
forming a hard mask layer including a pad oxide layer and a pad nitride layer on the substrate;
patterning the hard mask layer to form a first hard mask pattern exposing the substrate in the chip region and a second hard mask pattern exposing the substrate in the non-chip region; and
partially etching the exposed substrate in the chip region to form the isolation trench and partially etching the exposed substrate in the non-chip region to form the smaller aspect ratio trench.

11. The method of claim 8, wherein the insulating material comprises an oxide layer formed by a high-density plasma chemical vapor deposition (HDCVD) process.

12. The method of claim 8, further comprising partially removing the insulation material by a chemical mechanical polishing (CMP) process.

13. The method of claim 10, further comprising forming a buffer oxide layer on surfaces of the first and second hard mask patterns, side and bottom walls of the isolation trench, and side and bottom walls of the smaller aspect ratio trench.

14. The method of claim 8, further comprising planarizing the polysilicon layer by a chemical mechanical polishing (CMP) process.

15. The method of claim 8, further comprising removing portions of the tunnel oxide layer exposed by partially removing the polysilicon layer.

16. The method of claim 15, wherein removing portions of the tunnel oxide layer forms a tunnel oxide pattern in the chip region.

17. A method of manufacturing a semiconductor device, comprising:
preparing a substrate having a chip region that includes a cell region and a peripheral circuit region, and a predetermined region where an alignment mark is to be formed;
forming first hard mask patterns partially exposing a surface of the chip region and second hard mask patterns partially exposing a surface of the predetermined region, the partially exposed surface of the chip region being narrower in width than the partially exposed surface of the predetermined region;
partially etching the substrate using the first and second hard mask patterns as an etching mask to form a first trench in the chip regions and a second trench in the predetermined region, the first trench having a first aspect ratio greater than a second aspect ratio of the second trench;
forming a first structure between the first hard mask patterns and in the first trench, and a second structure between the second hard mask patterns and in the second trench, the first and second structures including a substantially same insulation material, the second structure having an upper face that is positioned on a plane lower than that on which an upper face of the first structure is positioned;
removing the first and second hard mask patterns to form a first structure pattern in the chip region and a second structure pattern in the predetermined region, the second structure exposing an upper end portion of the second trench;
sequentially forming a tunnel oxide layer and a polysilicon layer on portions of the chip region and the predetermined region exposed by removing the first and second hard mask patterns;
partially removing the polysilicon layer until a surface of the first structure pattern is exposed to separate a node of the polysilicon layer in the chip region and to fully fill up the second trench with the polysilicon layer;
partially removing the exposed surface of the first structure pattern to form a tunnel oxide layer pattern in the chip region, a polysilicon layer pattern in the chip region and an isolation layer in the first trench; and
substantially simultaneously removing a portion of the polysilicon layer pattern in the peripheral circuit region of the chip region and a portion of the polysilicon layer pattern in the second trench of the predetermined region to form an alignment mark having a stepped structure in the predetermined region, the stepped structure corresponding to the upper end portion of the second trench.

18. The method of claim 17, wherein the predetermined region comprises a scribe lane between chip regions.

19. The method of claim 17, wherein forming the first and second hard mask patterns comprises:
forming a hard mask layer including a pad oxide layer and a pad nitride layer on the substrate; and
patterning the hard mask layer.

20. The method of claim 17, wherein forming the first and second structures comprises:
forming an insulation layer on the substrate having the first and second hard mask patterns by a high-density plasma chemical vapor deposition (HDCVD) process; and
removing the insulation layer until surfaces of the first and second hard mask patterns are exposed by a chemical mechanical polishing (CMP) process.

21. The method of claim 17, wherein the polysilicon layer is removed by a chemical mechanical polishing (CMP) process.

22. The method of claim 17, further comprising:
forming a buffer oxide layer on surfaces of the first and second hard mask patterns, and on side and bottom walls of the first and second trenches; and
simultaneously removing the buffer oxide layer in the chip region and either a tunnel oxide layer or a second structure pattern in the predetermined region.

23. The method of claim 17, further comprising removing the tunnel oxide layer or the second structure pattern exposed through the polysilicon layer in the second trench.

24. The method of claim 23, further comprising partially removing the isolation layer.
